(19) United States
(12) Patent Application Publication
(10) Pub. No.: US 2025/0056919 A1
(43) Pub. Date: Feb. 13, 2025

(54) DISPLAY DEVICE AND METHOD OF REPAIRING THE SAME

(71) Applicant: Samsung Display Co., LTD., Yongin-si (KR)

(72) Inventors: KWIHYUN KIM, Yongin-si (KR); DONGWOO KIM, Yongin-si (KR); YEONKYUNG KIM, Yongin-si (KR); WONJUN LEE, Yongin-si (KR)

(21) Appl. No.: 18/733,703

(22) Filed: Jun. 4, 2024

(30) Foreign Application Priority Data
Aug. 11, 2023 (KR) 10-2023-0105850

(51) Int. Cl. H01L 33/00; H01L 25/075; H01L 33/62

(52) U.S. Cl. CPC H01L 33/0095; H01L 25/0753; H01L 33/62; H01L 2933/0066

(57) ABSTRACT

A display device includes: a substrate including a first pixel area and a second pixel area adjacent to each other along a first direction; a first pixel in the first pixel area on the substrate and including a first pixel electrode; a second pixel in the second pixel area on the substrate and including a second pixel electrode; and a repair pattern on the first pixel electrode and the second pixel electrode, contacting with the first pixel electrode and the second pixel electrode, and electrically connecting the first pixel and the second pixel.

### CROSS-REFERENCED TO RELATED APPLICATION

The present application claims priority to and the benefit of Korean Patent Application No. 10-2023-0105850, filed on Aug. 11, 2023, in the Korean Intellectual Property Office, the entire disclosure of which is incorporated herein by reference.

### BACKGROUND

### 1. Field

Aspects of some embodiments relate to a display device and method of repairing the display device.

### 2. Description of the Related Art

Recently, display products are being produced that are smaller, lighter, and have better performance thanks to technological advancements. Until now, existing cathode ray tube (CRT) display devices have been widely used with many advantages in terms of performance and price, but CRT display devices may be generally large and heavy, and may utilize relatively large amounts of power. Display devices that may be relatively thinner, lighter, more portable, and consume less power, such as plasma displays, liquid crystal displays, and organic light emitting display devices, are attracting attention.

Accordingly, if a defect occurs during the manufacturing process of a display device that has advantages such as miniaturization, weight reduction, and low power consumption, it is necessary to repair it.

The above information disclosed in this Background section is only for enhancement of understanding of the background and therefore the information discussed in this Background section does not necessarily constitute prior art.

### SUMMARY

Aspects of some embodiments include a display device that can be repaired.

A display device according to some embodiments of the present invention may include a substrate including a first pixel area and a second pixel area adjacent to each other along a first direction, a first pixel electrode in the first pixel area on the substrate and including a first pixel electrode, a second pixel in the second pixel area on the substrate and including a second pixel electrode, and a repair pattern on the first pixel electrode and the second pixel electrode, contacting with the first pixel electrode and the second pixel electrode, and electrically connecting the first pixel and the second pixel.

According to some embodiments, the display device may further include a pixel defining layer covering a portion of the first pixel electrode and a portion of the second pixel electrode, and wherein the repair pattern may be on the pixel defining layer.

According to some embodiments, the repair pattern may include a metal material.

According to some embodiments, each of the first pixel electrode and the second pixel electrode may include a body portion and a protrusion protruding from one side of the body portion.

According to some embodiments, in a plan view, the first pixel electrode and the second pixel electrode are line symmetrical with respect to a reference line extending in a second direction intersecting the first direction between the first pixel electrode and the second pixel electrode, and the first pixel electrode, the protrusion of the pixel electrode may protrude from the body of the first pixel electrode in the first direction, and the protrusion of the second pixel electrode may protrude from the body of the second pixel electrode in a direction opposite to the first direction.

According to some embodiments, in a plan view, the first pixel electrode and the second pixel electrode may be repeatedly arranged in the same shape along the first direction, the protrusion of the first pixel electrode may extend from the body portion of the first pixel electrode in the first direction, and the protrusion of the second pixel electrode may protrude from the body of the second pixel electrode in the first direction.

According to some embodiments, a color of light emitted by the first pixel may be the same as a color of light emitted by the second pixel.

A display device according to some embodiments of the present invention may include a substrate including a first pixel area and a second pixel area, a first pixel in the first pixel area on the substrate and including a first pixel electrode, a second pixel in the second pixel area on the substrate and including a second pixel electrode, and repair pattern below the first pixel electrode and the second pixel electrode, contact with the first pixel electrode and the second pixel electrode, and electrically connecting the first pixel and the second pixel electrode.

According to some embodiments, the repair pattern may overlap the first pixel electrode and the second pixel electrode in a plan view.

According to some embodiments, a color of light emitted by the first pixel may be the same as a color of light emitted by the second pixel.

According to some embodiments, the display device may further include a first welding part contacting with the first pixel electrode and a second welding part contacting with the second pixel electrode, and wherein the first welding part and the second welding part may contact with the repair pattern.

A method of repairing a display device according to some embodiments of the present invention including a substrate including a first pixel area in the first pixel area and including a first pixel electrode, and a second pixel in the second pixel area and including a second pixel electrode may include cutting a portion of the first electrode, electrically connecting the first pixel electrode and the second pixel electrode through a repair pattern contacting with the first pixel electrode and the second pixel electrode, and applying an additional data voltage to the first pixel and the second pixel.

According to some embodiments, in the cutting the portion of the first pixel electrode, the first pixel electrode may be cut using a laser.

According to some embodiments, the first pixel electrode may include a body portion and a protrusion protruding from one side of the body portion, and in the cutting the portion of the first pixel electrode, the protrusion may be cut from the body portion.

According to some embodiments, the method of repairing the display device may further include forming a light emitting layer on the first pixel electrode and the second pixel electrode and forming a common electrode on the light emitting layer, and the forming the light emitting layer and the forming the common electrode may be performed after electrically connecting the first pixel electrode and the second pixel electrode.

According to some embodiments, the method of repairing the display device may further include a forming a pixel defining layer covering a portion of the first pixel electrode and a portion of the second pixel electrode, and the electrically connecting the first pixel electrode and the second pixel electrode may include a forming the repair pattern on the pixel defining layer.

According to some embodiments, the repair pattern may be formed using a laser chemical vapor deposition (CVD) method.

According to some embodiments, the repair pattern may be below the first pixel electrode and the second pixel electrode, may overlap the first pixel electrode and the second pixel electrode in a plan view, and the connecting the first pixel electrode and the second pixel electrode may include a forming a first welding part contacting with the repair pattern and the first pixel electrode and a forming a second welding part contacting with the repair pattern and the second pixel electrode.

According to some embodiments, in the applying the additional data voltage, a basic current due to the basic data voltage and an additional current due to the additional data voltage may be applied to each of the first pixel electrode and the second pixel electrode.

According to some embodiments, a magnitude of the basic current applied to each of the first pixel and the second pixel may be the same as a magnitude of the additional current applied to each of the first pixel and the second pixel.

Therefore, before forming a light emitting layer on the first pixel electrode and the second pixel electrode, repair may be performed to prevent bright spots and dark spots from occurring due to defective pixels. Accordingly, productivity and yield of the display device may be relatively improved. Also, the design constraints of the display device for repair may be relatively minimized or reduced, so that the repair pattern may be relatively easily formed even when the display device has a relatively high degree of integration.

Additionally, according to the repair method according to some embodiments of the present invention, after forming the repair pattern, an additional data voltage may be applied to the first pixel and the second pixel to prevent current reduction due to repair. Accordingly, the phenomenon of luminance being lowered due to repair may be prevented or reduced.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view showing a display device according to some embodiments of the present invention.

FIG. 2 is a circuit diagram showing an example of a pixel included in the display device of FIG. 1.

FIG. 3 is an enlarged view showing an example of the area A of FIG. 1.

FIG. 4 is an enlarged view showing another example of the area A of FIG. 1.

FIG. 5 is a cross-sectional view taken along the line I-I′ of FIG. 3.

FIG. 6 to 10 are diagrams showing a repair method for a display device according to some embodiments of the present invention.

FIG. 11 is an enlarged view showing still another example of the area A of FIG. 1.

FIG. 12 is an enlarged view showing still another example of the area A of FIG. 1.

FIG. 13 is a cross-sectional view taken along the line II-II′ of FIG. 11.

FIG. 14 to 16 are diagrams showing a repair method for a display device according to some embodiments of the present invention.

FIG. 17 is a plan view showing a display device according to some embodiments of the present invention.

FIG. 18 is an enlarged view showing an example of part B of FIG. 17.

FIG. 19 is a cross-sectional view taken along the line III-III′ of FIG. 18.

### DETAILED DESCRIPTION

Aspects of some illustrative, non-limiting embodiments will be more clearly understood from the following detailed description in conjunction with the accompanying drawings.

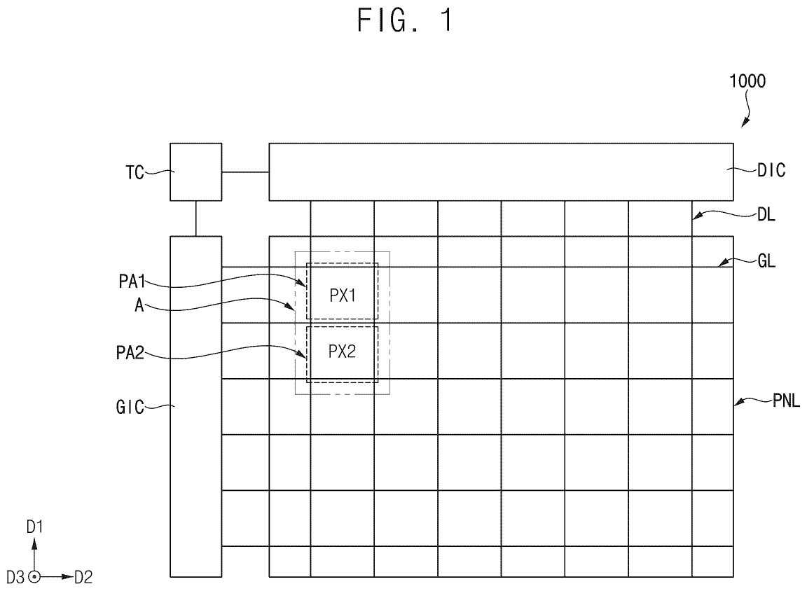

FIG. 1 is a plan view showing a display device according to some embodiments of the present invention.

Referring to FIG. 1, a display device 1000 may include a display panel PNL, a data driver DIC, a gate driver GIC, and a control unit TC.

A plurality of pixels and signal lines capable of applying electrical signals to the pixels may be located on the display panel PNL.

The pixels may be repeatedly arranged in a matrix form or arrangement (e.g., rows and columns) on a plane (or in a plan view, or in a direction perpendicular to a plane of the display surface of the display device 1000, e.g., in a view from the direction D3). For example, the pixels may be repeatedly arranged in a first direction D1 and a second direction D2 intersecting the first direction D1. The signal lines may include data lines DL extending in the first direction D1 and gate lines GL extending in the second direction D2. The gate lines GL may be arranged to be spaced apart along the first direction D1 and may transmit gate signals to the pixels. The data lines DL may be arranged to be spaced apart along the second direction D2 and may transmit data signals to the pixels. According to some embodiments, each of the pixels may be connected to at least one corresponding gate line among the gate lines GL and at least one corresponding data line among the data lines DL.

The data driver DIC may be connected to the data lines DL and may supply a data signal to the data lines DL in response to a data control signal provided from the control unit TC.

The gate driver GIC may be connected to the gate lines GL, generate a gate signal in response to the gate control signal provided from the control unit TC, and sequentially supplies the gate signal to the gate lines GL.

Hereinafter, as a display device according to some embodiments of the present invention, an ultra-small light emitting diode display (or micro light-emitting diode display) including ultra-small light-emitting diodes (or micro light-emitting diodes) will be described as an example, the present invention may not be limited to the embodiments. Optionally, the display device 1000 may be an inorganic light emitting display, a quantum dot light emitting display, or the like.

The display device 1000 (eg, display panel PNL) may be divided into a plurality of pixel areas. The pixel areas may be repeatedly arranged along the first direction D1 and the second direction D2. At this time, each of the pixel areas may be a division of a repetitive structure and does not mean a break in the structure.

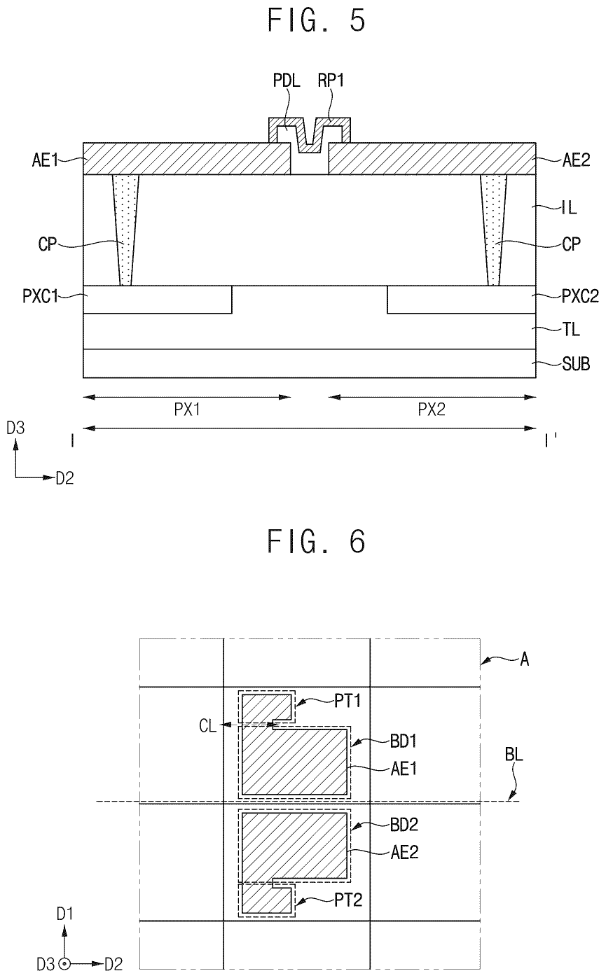

Various components constituting the display device 1000 may be located on a substrate (eg, a substrate SUB in FIG. 5). Accordingly, the substrate SUB may include the pixel areas.

The pixels may be respectively arranged in the pixel areas. In other words, one pixel may be located in each of the pixel areas.

According to some embodiments, the pixel areas may include a first pixel area PA1 and a second pixel area PA2. The first pixel area PA1 and the second pixel area PA2 may be adjacent to each other along the first direction D1.

A first pixel PX1 may be located in the first pixel area PA1, and a second pixel PX2 may be located in the second pixel area PA2. Accordingly, the first pixel PX1 and the second pixel PX2 may be adjacent to each other along the first direction D1.

According to some embodiments, a color of light emitted by the first pixel PX1 and a color of light emitted by the second pixel PX2 may be the same. In other words, a color of light emitted from the first pixel area PA1 and a color of light emitted from the second pixel area PA2 may be the same.

For example, a color of light emitted from the first pixel PX1 and a color of light emitted from the second pixel PX2 may be red. For another example, a color of light emitted from the first pixel PX1 and a color of light emitted from the second pixel PX2 may be green. For still another example, a color of light emitted from the first pixel PX1 and a color of light emitted from the second pixel PX2 may be blue. However, the present invention may not be necessarily limited to this, and a color of light emitted from the first pixel PX1 and the second pixel PX2 may vary depending on the embodiments.

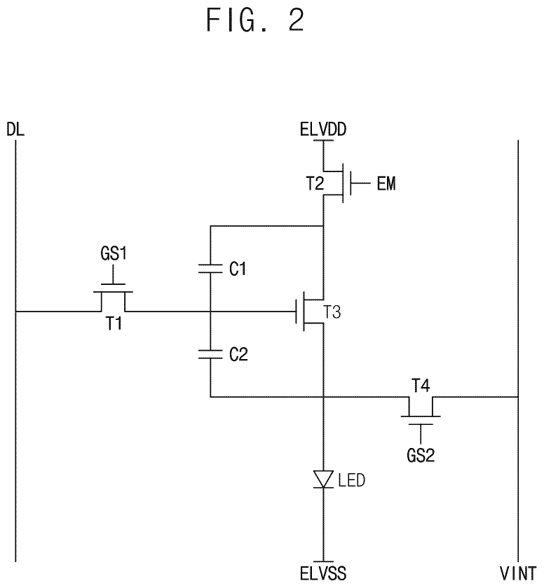

FIG. 2 is a circuit diagram showing an example of a pixel included in the display device of FIG. 1.

Referring to FIG. 2, each of the pixels (e.g., the first pixel PX1 and the second pixel PX2 in FIG. 1) may include first to fourth transistors T1, T2, T3, and T4, a first capacitor C1, a second capacitor C2, and a light emitting device LED.

The first transistor T1 may include a gate electrode, a first electrode, and a second electrode. A first gate signal GS1 transmitted from the gate lines GL may be applied to the gate electrode of the first transistor T1. A data signal transmitted through the data lines DL may be applied to the first electrode of the first transistor T1. The second electrode of the first transistor T1 may be connected to the first capacitor C1 and the second capacitor C2.

The second transistor T2 may include a gate electrode, a first electrode, and a second electrode. An emission control signal EM may be applied to the gate electrode of the second transistor T2. A driving voltage ELVDD may be applied to the first electrode of the second transistor T2. The second electrode of the second transistor T2 may be connected to the first capacitor C1.

The third transistor T3 may include a gate electrode, a first electrode, and a second electrode. The gate electrode of the third transistor T3 may be connected to the second electrode of the first transistor T1. The first electrode of the third transistor T3 may be connected to a second electrode of the fourth transistor T4. The second electrode of the third transistor T3 may be connected to the second electrode of the second transistor T2.

The fourth transistor T4 may include a gate electrode, a first electrode, and a second electrode. A second gate signal GS2 transmitted from the gate lines GL may be applied to the gate electrode of the fourth transistor T4. An initialization voltage VINT may be applied to the first electrode of the fourth transistor T4. The second electrode of the fourth transistor T4 may be connected to the first electrode of the third transistor T3.

The first capacitor C1 may include a first electrode and a second electrode. The first electrode of the first capacitor C1 may be connected to the second electrode of the second transistor T2. The second electrode of the first capacitor C1 may be connected to the second electrode of the first transistor T1.

The second capacitor C2 may include a first electrode and a second electrode. The first electrode of the second capacitor C2 may be connected to the first electrode (pixel electrode or anode) of the light emitting device LED. The second electrode of the second capacitor C2 may be connected to the second electrode of the first transistor T1.

The light emitting device LED may include a first electrode and a second electrode. The first electrode of the light emitting device LED may be connected to the first electrode of the second capacitor. A common voltage ELVSS may be applied to the second electrode of the light emitting device LED.

Meanwhile, in FIG. 2 of this specification, a pixel having a 4T2C structure is shown, but the structure of the pixel of the present invention may not be limited to this and may be configured in various ways, such as 2T1 C, 3T1 C, 5T2C, 6T2C, 7T2C, and the like. That is, according to various embodiments, the pixel may include additional components or fewer components without departing from the spirit and scope of embodiments according to the present disclosure.

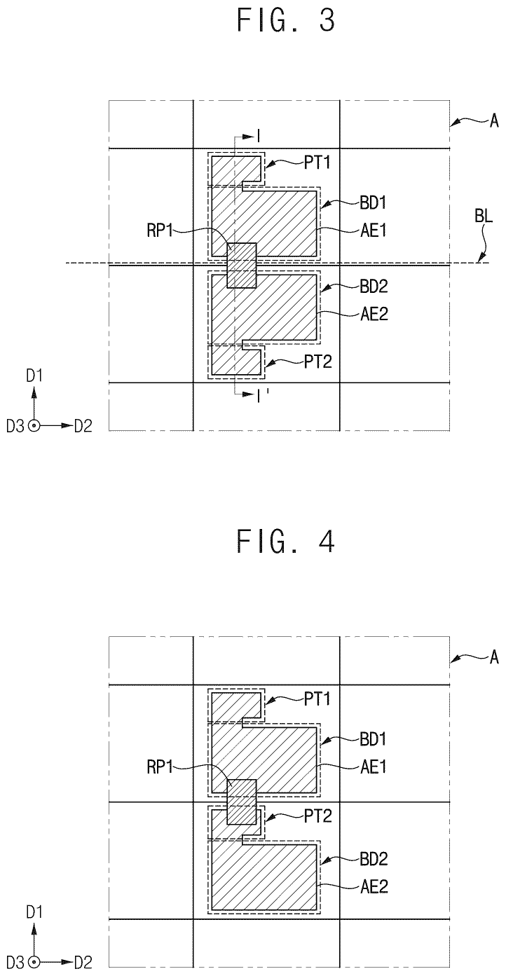

FIG. 3 is an enlarged view showing an example of area A of FIG. 1. For example, FIG. 3 is an enlarged view schematically showing an example of the arrangement of the first and the second pixel electrodes AE1 and AE2 and the repair pattern RP1 in area A of FIG. 1.

Referring to FIGS. 1 and 3, the first pixel electrode AE1 of the first pixel PX1 may be located in the first pixel area PA1, the second pixel electrode AE2 of the two pixels PX2 may be located in the second pixel area PA2.

Accordingly, the first pixel electrode AE1 and the second pixel electrode AE2 may be located adjacent to each other along the first direction D1. The repair pattern RP1 may be located on the first pixel electrode AE1 and the second pixel electrode AE2.

The first pixel electrode AE1 may include a first body portion BD1 and a first protrusion PT1 protruding from one side of the first body portion BD1. For example, the first protrusion PT1 may protrude from one side of the first body BD1 in the first direction D1. However, embodiments according to the present invention are not necessarily limited thereto.

The first pixel electrode AE1 may include metal, alloy, metal nitride, conductive metal oxide, transparent conductive material, and the like. These may be used alone or in combination with each other. For example, the first pixel electrode AE1 may be an anode electrode.

The second pixel electrode AE2 may include a second body portion BD2 and a second protrusion PT2 protruding from one side of the second body portion BD2. For example, the second protrusion PT2 may protrude from one side of the first body BD1 in a direction opposite to the first direction D1. However, embodiments according to the present invention are not necessarily limited thereto.

The second pixel electrode AE2 may include metal, alloy, metal nitride, conductive metal oxide, transparent conductive material, and the like. These may be used alone or in combination with each other. For example, the second pixel electrode AE2 may be an anode electrode.

According to some embodiments, the first pixel electrode AE1 and the second pixel electrode AE2 may be line symmetrical with respect to the reference line BL on a plane. The reference line BL may be a line extending in the second direction D2 between the first pixel electrode AE1 and the second pixel electrode AE2. Accordingly, as described above, the first protrusion PT1 of the first pixel electrode AE1 may protrude in the first direction D1 from the first body portion BD1 of the first pixel electrode AE1. In contrast, the second protrusion PT2 of the second pixel electrode AE2 may protrude from the second body portion BD2 of the second pixel electrode AE2 in a direction opposite to the first direction. However, embodiments according to the present invention are not necessarily limited thereto.

The repair pattern RP1 may be located on the first pixel electrode AE1 and the second pixel electrode AE2. The repair pattern RP1 may contact the first pixel electrode AE1 and the second pixel electrode AE2. Accordingly, the repair pattern RP1 may electrically connect the first pixel PX1 and the second pixel PX2. The repair pattern RP1 may include metal, alloy, metal nitride, conductive metal oxide, transparent conductive material, and the like. These may be used alone or in combination with each other.

FIG. 4 is an enlarged view showing another example of area A of FIG. 1.

For example, FIG. 4 is an enlarged view schematically showing another example of the arrangement of the first and the second pixel electrodes AE1 and AE2 and the repair pattern RP1 in area A of FIG. 1.

According to some embodiments, the first pixel electrode AE1 and the second pixel electrode AE2 may be repeatedly arranged in the same shape along the first direction D1 on a plane. Accordingly, the first protrusion PT1 of the first pixel electrode AE1 may protrude from the first body portion BD1 of the first pixel electrode AE1 in the first direction D1, and the second protrusion PT2 of the second pixel electrode AE2 may protrude from the second body portion BD2 of the second pixel electrode AE2 in the first direction D1.

FIG. 5 is a cross-sectional view taken along the line I-I′ of FIG. 3.

Referring to FIGS. 1, 3, and 5, the display device 1000 includes a substrate SUB, a transistor layer TL, an insulating layer IL, a connection pattern CP, the first pixel electrode AE1, the second pixel electrode AE2, a pixel defining layer PDL, and the repair pattern RP1.

According to some embodiments, the substrate SUB may include a silicon wafer. The substrate SUB may be a support member for supporting other components of the display device 1000.

The transistor layer TL may be located on the substrate SUB. The transistor layer TL may include a first pixel circuit unit PXC1 and a second pixel circuit unit PXC2. The first pixel circuit unit PXC1 and the second pixel circuit unit PXC2 may include various driving elements, wiring, and the like for driving the light-emitting element of the first pixel PX1 and the light-emitting element of the second pixel PX2.

The insulating layer IL may be located on the transistor layer TL. The insulating layer IL may be located in the first and the second pixel areas PA1 and PA2. The insulating layer IL may prevent contact between the first and the second pixel electrodes AE1 and AE2 and the first and the second pixel circuit units PXC1 and PXC2. The insulating layer IL may include an organic material. Examples of the organic material that may be used as the insulating layer IL may include photoresist, polyacrylic resin, polyimide resin, and acrylic resin. These may be used alone or in combination with each other.

Contact holes penetrating the insulating layer IL may be defined in the insulating layer IL. The contact holes may respectively expose the first pixel circuit unit PXC1 and the second pixel circuit unit PXC2. Each of the contact holes may be filled with the connection pattern CP. The connection pattern CP may be electrically connected to the first pixel circuit PXC1 and the second pixel circuit PXC2. For example, the connection pattern CP located in the first pixel area PA1 may be electrically connected to the first pixel circuit unit PXC1, and the connection pattern CP located in the second pixel area PA2 may be electrically connected to the second pixel circuit unit PXC2. According to some embodiments, the connection pattern CP may include a conductive material. For example, the connection pattern CP may include tungsten (W).

The first pixel electrode AE1 and the second pixel electrode AE2 may be located on the insulating layer IL. For example, the first pixel electrode AE1 may be located on the insulating layer IL to correspond to the first pixel area PA1, and the second pixel electrode AE2 may be located on the insulating layer IL to correspond to the second pixel area PA2. The first pixel electrode AE1 may be electrically connected to the first pixel circuit PXC1 through the connection pattern CP, and the second pixel electrode AE2 may be electrically connected to the first pixel circuit PXC1 through the connection pattern CP.

The pixel defining layer PDL may be located on the insulating layer IL, the first pixel electrode AE1, and the second pixel electrode AE2. The pixel defining layer PDL may cover a portion of each of the first pixel electrode AE1 and the second pixel electrode AE2. That is, the pixel defining layer PDL may expose a portion of each of the first pixel electrode AE1 and the second pixel electrode AE2. For example, the pixel defining layer PDL may cover a side of each of the first pixel electrode AE1 and the second pixel electrode AE2, and expose the central portion of each of the first pixel electrode AE1 and the second pixel electrode AE2. The pixel defining layer PDL may prevent electrical connection between the first pixel electrode AE1 and the second pixel electrode AE2. The pixel defining layer PDL may be formed of an organic material. Examples of the organic material may include photoresist, polyacrylic resin, polyimide resin, and acrylic resin. These may be used alone or in combination with each other.

The repair pattern RP1 may be located on the pixel defining layer PDL, the first pixel electrode AE1, and the second pixel electrode AE2. The repair pattern RP1 may not be disconnected on the pixel defining layer PDL. The repair pattern RP1 may be in contact with the first pixel electrode AE1 and the second pixel electrode AE2, and may electrically connect the first pixel PX1 and the second pixel PX2. Accordingly, the repair pattern RP1 may allow the same current to flow through the first pixel electrode AE1 and the second pixel electrode AE2. The repair pattern RP1 may include metal, alloy, metal nitride, conductive metal oxide, transparent conductive material, and the like. These may be used alone or in combination with each other.

That is, according to some embodiments, the first pixel electrode AE1 and the second pixel electrode AE2 may be located adjacent to each other in the first direction D1, and the repair pattern RP1 may overlap the first pixel electrode AE1 and the second pixel electrode AE2 on the first pixel electrode AE1 and the second pixel electrode AE2. Accordingly, when a defect occurs in any one of adjacent pixels, the repair pattern RP1 may repair the defective pixel. For example, when a defect occurs in one of the first pixel PX1 and the second pixel PX2, the defective pixel may be repaired through the repair pattern RP1.

FIG. 6 to 10 are diagrams showing a repair method for a display device according to some embodiments of the present invention.

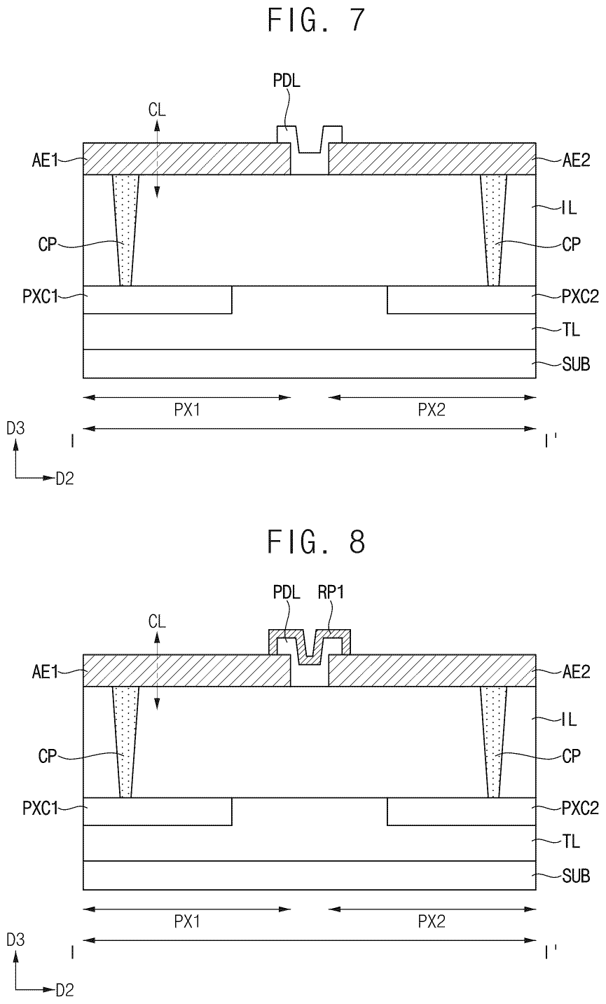

Referring to FIGS. 6 and 7, first, the transistor layer TL, the insulating layer IL, the connection pattern CP, the first and the second pixel electrodes AE1, AE2, and the pixel defining layer PDL may be formed on the substrate SUB.

Thereafter, when the first pixel electrode AE1 is defective, a portion of the first pixel electrode AE1 may be cut. For example, if bright or dark spots may occur in the first pixel (PX1, see FIG. 1) due to a defect in the first pixel electrode AE1, a portion of the first pixel electrode AE1 may be cut.

For example, when the first pixel electrode AE1 is defective, the first protrusion PT1 of the first pixel electrode AE1 may be cut from the first body portion BD1. That is, a cutting line CL may be defined between the first protrusion PT1 and the first body part BD1.

According to some embodiments, the first pixel electrode AE1 may be cut using a laser. For example, the laser used for cutting may be an ultra-fast laser. For example, the ultra-fast laser may be a picosecond laser, a femtosecond laser, or an attosecond laser. However, embodiments according to the present invention are not necessarily limited thereto.

Thereafter, referring to FIG. 8, the repair pattern RP1 may be formed on the pixel defining layer PDL, the first pixel electrode AE1, and the second pixel electrode AE2. The repair pattern RP1 may be formed so as not to be disconnected on the pixel defining layer PDL. The repair pattern RP1 may be formed to electrically connect the first pixel PX1 and the second pixel PX2 contacting with the first pixel electrode AE1 and the second pixel electrode AE2. For example, the repair pattern RP1 may cause the same current to flow through the first pixel electrode AE1 and the second pixel electrode AE2.

According to some embodiments, the repair pattern RP1 may be formed using a chemical vapor deposition (CVD) method. In this case, the chemical vapor deposition (CVD) method refers to a method of locally irradiating a laser beam while gasifying a material to be deposited, and depositing the material at the irradiated location.

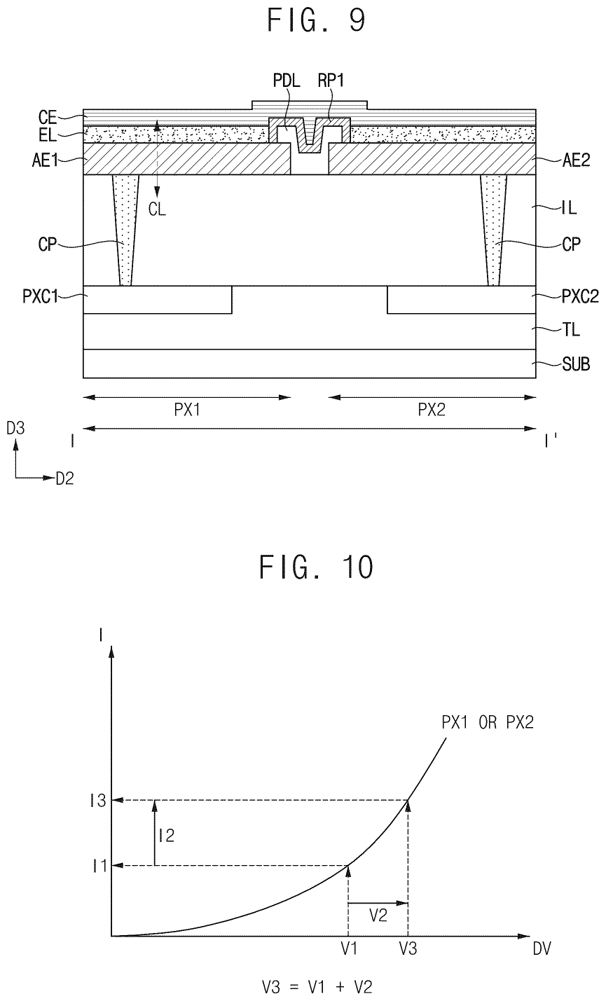

Referring to FIG. 9, a light emitting layer EL may be formed on the first pixel electrode AE1 and the second pixel electrode AE2. The light emitting layer EL may be disconnected by the pixel defining layer PDL. Accordingly, the light emitting layer EL formed on the first pixel electrode AE1 and the light emitting layer EL located on the second pixel electrode AE2 may not be electrically connected.

Thereafter, a common electrode CE may be formed on the light emitting layer EL and the pixel defining layer PDL. Specifically, the common electrode CE may be formed by being connected to the first pixel electrode AE1, the second pixel electrode AE2, and the pixel defining layer PDL without being disconnected.

For example, when the first pixel electrode AE1 is defective, a portion of the first pixel electrode AE1 may be cut, the repair pattern RP1 may be formed, and then the light emitting layer EL and the common electrode may be formed. Specifically, after the first pixel electrode AE1 and the second pixel electrode AE2 are electrically connected by the repair pattern RP1, the light emitting layer EL and the common electrode CE may be formed.

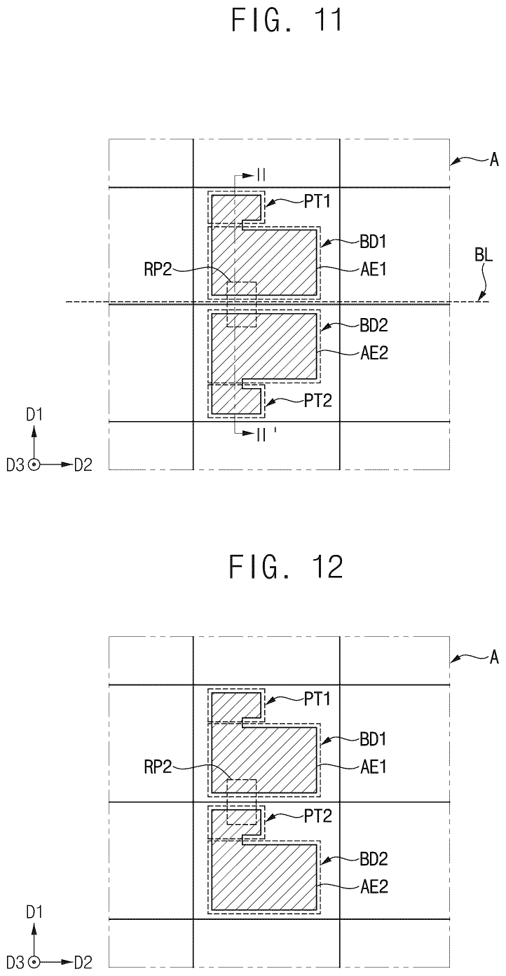

Thereafter, referring to FIG. 10, an additional data voltage V2 may be applied to the first pixel PX1 and the second pixel PX2. According to some embodiments, the additional data voltage V2 may be applied together with the basic data voltage V1.

That is, a basic current I1 due to the basic data voltage V1 and an additional current I2 due to the additional data voltage V2 may be applied to the first pixel PX1 and the second pixel PX2. Accordingly, the final data voltage V3, which is the sum of the basic data voltage V1 and the additional data voltage V2, may be applied to the first pixel PX1 and the second pixel PX2.

As the first pixel PX1 and the second pixel PX2 are electrically connected by the repair pattern RP1, the first pixel PX1 and the second pixel PX2 may share a current applied the basic voltage V1. Accordingly, compared to the case where the first pixel PX1 and the second pixel PX2 are not electrically connected by the repair pattern RP1, a magnitude of the current applied by the basic data voltage V1 to each of the first pixel PX1 and the second pixel PX2 may decrease when the first pixel PX1 and the second pixel PX2 are electrically connected by the repair pattern RP1.

According to some embodiments, an additional data voltage V2 may be applied to the first pixel PX1 and the second pixel PX2, and accordingly, the additional current I2 may be applied to the first pixel PX1 and the second pixel PX2. Accordingly, the final current I3, which is the sum of the basic current I1 and the additional current I2, may be applied to each of the first pixel PX1 and the second pixel PX2.

That is, a magnitude of the additional data voltage V2 may be determined so that a current equal to the amount reduced by repair may be applied to each of the first pixel PX1 and the second pixel PX2. In other words, the additional data voltage V2 may be a compensation data voltage to compensate for a decrease in current for each pixel due to the repair pattern RP1. Accordingly, even when the repair pattern RP1 is included, a decrease in luminance of the first pixel PX1 and the second pixel PX2 may be prevented or reduced.

According to some embodiments, a magnitude of the basic current I1 applied to each of the first pixel PX1 and the second pixel PX2 and a magnitude of the additional currents I2 applied to each of the first pixel PX1 and the second pixel PX2 may be equal or substantially equal to each other.

That is, as the first pixel PX1 and the second pixel PX2 are electrically connected by the repair pattern RP1, the first pixel PX1 and the second pixel PX2 may share a current applied by the data voltage V1 in half. Accordingly, compared to the case where the first pixel PX1 and the second pixel PX2 are not electrically connected by the repair pattern RP1, a magnitude of the current applied by the basic data voltage V1 to each of the first pixel PX1 and the second pixel PX2 is approximately half when the first pixel PX1 and the second pixel PX2 are electrically connected by the repair pattern RP1.

Accordingly, a magnitude of the additional current I2 applied by the additional data voltage V2 may be substantially the same as a magnitude of the basic current I1. However, the present invention may not be necessarily limited thereto.

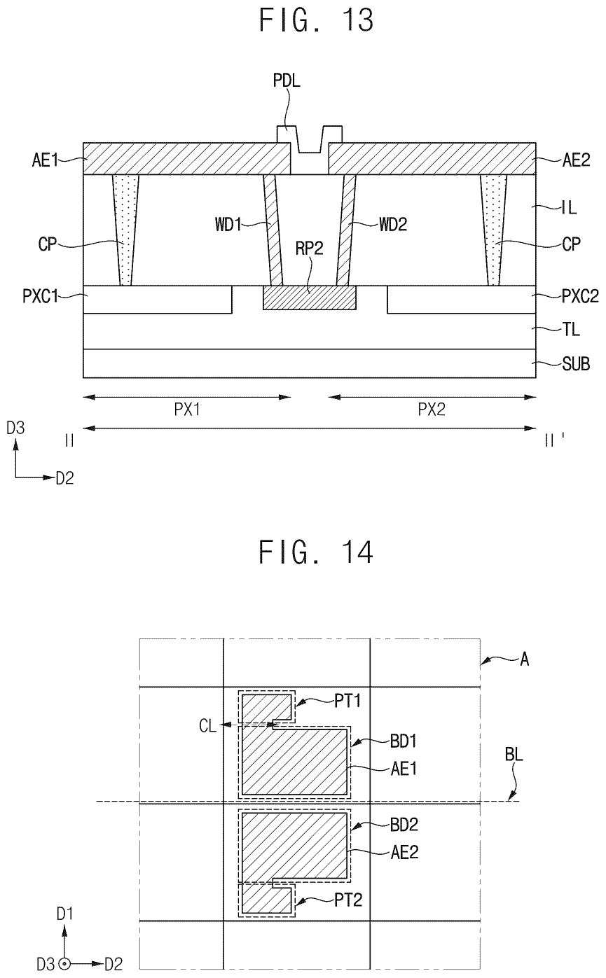

FIG. 11 is an enlarged view showing still another example of area A of FIG. 1. FIG. 12 is an enlarged view showing still another example of area A of FIG. 1.

For example, FIG. 11 is an enlarged view schematically showing an example of the arrangement of the first and the second pixel electrodes AE1 and AE2 and the repair pattern RP2 in area A of FIG. 1. Configurations described with reference to FIG. 11 may be substantially the same as those described with reference to FIG. 3 except for the repair pattern RP2. Therefore, overlapping explanations may be omitted or simplified.

For example, FIG. 12 is an enlarged view schematically showing an example of the arrangement of the first and the second pixel electrodes AE1 and AE2 and the repair pattern RP2 in area A of FIG. 1. Configurations described with reference to FIG. 12 may be substantially the same as those described with reference to FIG. 4 except for the repair pattern RP2. Therefore, overlapping explanations may be omitted or simplified.

That is, the configuration shown in FIGS. 11 and 12 may be substantially the same as the configuration shown in FIGS. 3 and 4, respectively, except that including the repair pattern RP2 instead of the repair pattern RP1.

Referring to FIGS. 1, 11, and 12, the first pixel electrode AE1 of the first pixel PX1 may be located in the first pixel area PA1, and the second pixel electrode AE2 of the second pixel PX2 may be located in the second pixel area PA2. The repair pattern RP2 may be located below the first pixel electrode AE1 and the second pixel electrode AE2. The repair pattern RP2 may overlap the first pixel electrode AE1 and the second pixel electrode AE2 on a plane.

According to some embodiments, the repair pattern RP2 may contact the first pixel electrode AE1 and the second pixel electrode AE2. Accordingly, the repair pattern RP2 may electrically connect the first pixel PX1 and the second pixel PX2.

According to some embodiments, as shown in FIG. 11, even when the repair pattern RP2 electrically connecting the first pixel electrode AE1 and the second pixel electrode AE2 is located at the bottom, the first pixel electrode AE1 and the second pixel electrode AE2 may be line symmetrical with respect to the reference line BL on a plane.

Also, according to some embodiments, as shown in FIG. 12, even when the repair pattern RP2 electrically connecting the first pixel electrode AE1 and the second pixel electrode AE2 is located at the bottom, the first pixel electrode AE1 and the second pixel electrode AE2 may be repeatedly arranged in the same shape along the first direction D1 on a plane.

FIG. 13 is a cross-sectional view taken along the line II-II′ of FIG. 11.

The configurations described with reference to FIG. 13 may be substantially the same as those shown in FIG. 5, except that including the repair pattern RP2, a first welding part WD1, and a second welding part WD2.

That is, the configuration shown in FIG. 13 may be substantially the same as those shown in of FIG. 5 except that including the repair pattern RP2, the first welding part WD1, and a second welding part WD2 instead of the repair pattern RP1.

Referring to FIGS. 1, 11, and 13, the display device 1000 may include the substrate SUB, the transistor layer TL, the connection pattern CP, the insulating layer IL, the first welding part WD1, the second welding part WD2, the first pixel electrode AE1, the second pixel electrode AE2, and the pixel defining layer PDL.

According to some embodiments, the transistor layer TL may include the repair pattern RP2. For example, the repair pattern RP2 may be located on the same layer as one of several metal patterns located on the transistor layer TL. In other words, the repair pattern RP2 may be formed in the same process as any one of several metal patterns located on the transistor layer TL.

For example, the repair pattern RP2 may be located on the same layer as one of several metal patterns forming the first pixel circuit unit PXC1 and/or the second pixel circuit unit PXC2. In other words, the repair pattern RP2 may be formed together with one of several metal patterns forming the first pixel circuit unit PXC1 and/or the second pixel circuit unit PXC2 in the same process.

The repair pattern RP2 may electrically connect the first pixel PX1 and the second pixel PX2. For example, the repair pattern RP2 may cause the same current to flow through the first pixel electrode AE1 and the second pixel electrode AE2. The repair pattern RP2 may include metal, alloy, metal nitride, conductive metal oxide, transparent conductive material, and the like. These may be used alone or in combination with each other.

For example, the repair pattern RP2 may electrically connect the first pixel PX1 and the second pixel PX2 through a welding process. That is, the first welding part WD1 may be formed through the welding process in an area where the repair pattern RP2 and the first pixel electrode AE1 overlap, and the second welding part WD2 may be formed through the welding process in an area where the repair pattern RP2 and the electrode AE2 overlaps. Therefore, the first welding part WD1 may be in contact with the first pixel electrode AE1 and the repair pattern RP2, and the second welding part WD2 may be in contact with the second pixel electrode AE2 and the repair pattern RP2.

Accordingly, the repair pattern RP2 may be electrically connected to the first pixel electrode AE1 through the first welding part WD1, and the second pixel electrode AE2 through the second welding part WD2. In other words, the first pixel electrode AE1 and the second pixel electrode AE2 may be electrically connected through the first welding part WD1 and the second welding part WD2 with the repair pattern RP2 interposed.

The first welding part WD1 and the second welding part WD2 may include metal, alloy, metal nitride, conductive metal oxide, transparent conductive material, and the like. These may be used alone or in combination with each other.

FIGS. 14 to 16 are diagrams showing a repair method for a display device according to some embodiments of the present invention.

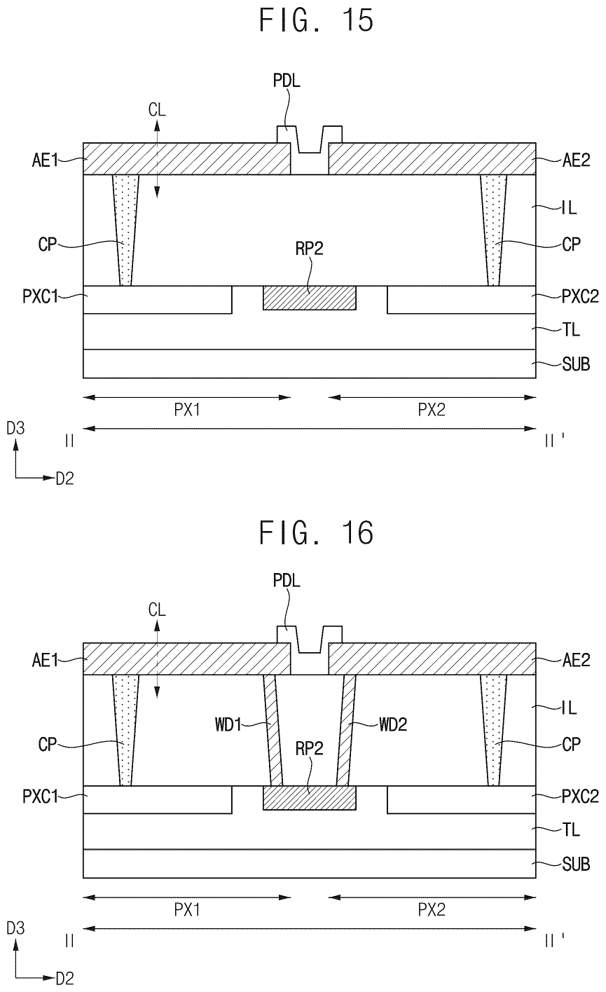

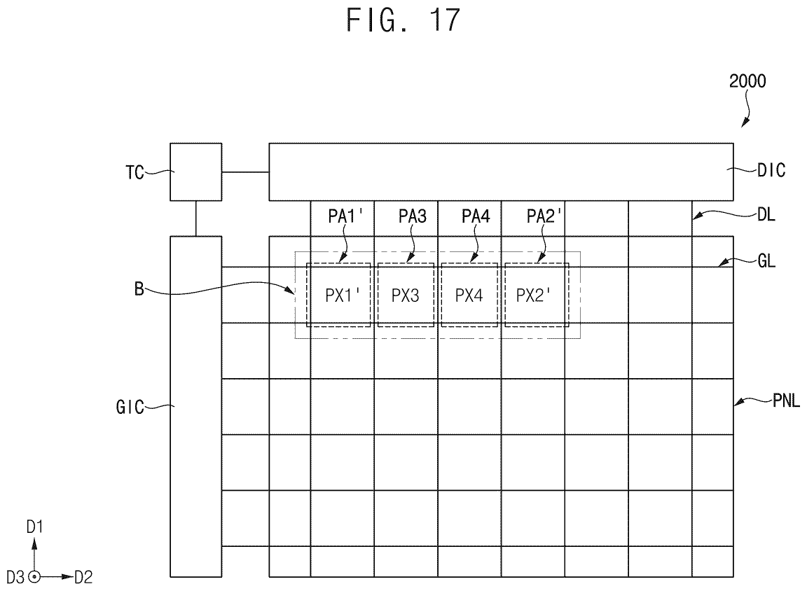

Referring to FIGS. 14 and 15, first, the transistor layer TL, the insulating layer IL, the connection pattern CP, the first and the second pixel electrodes AE1 and AE2, and the pixel defining layer PDL may be formed on the substrate SUB.

Meanwhile, the transistor layer TL may include the first pixel circuit unit PXC1, the second pixel circuit unit PXC2, and the repair pattern RP2. According to some embodiments, the repair pattern RP2 may be formed together with one of several metal patterns forming the first pixel circuit unit PXC1 and/or the second pixel circuit unit PXC2 in the same process.

Thereafter, when the first pixel electrode AE1 is defective, a portion of the first pixel electrode AE1 may be cut. For example, if bright or dark spots may occur in the first pixel (PX1, see FIG. 1) due to a defect in the first pixel electrode AE1, the portion of the first pixel electrode AE1 may be cut.

For example, when the first pixel electrode AE1 is defective, the first protrusion PT1 of the first pixel electrode AE1 may be cut from the first body portion BD1. That is, the cutting line CL may be defined between the first protrusion PT1 and the first body part BD1.

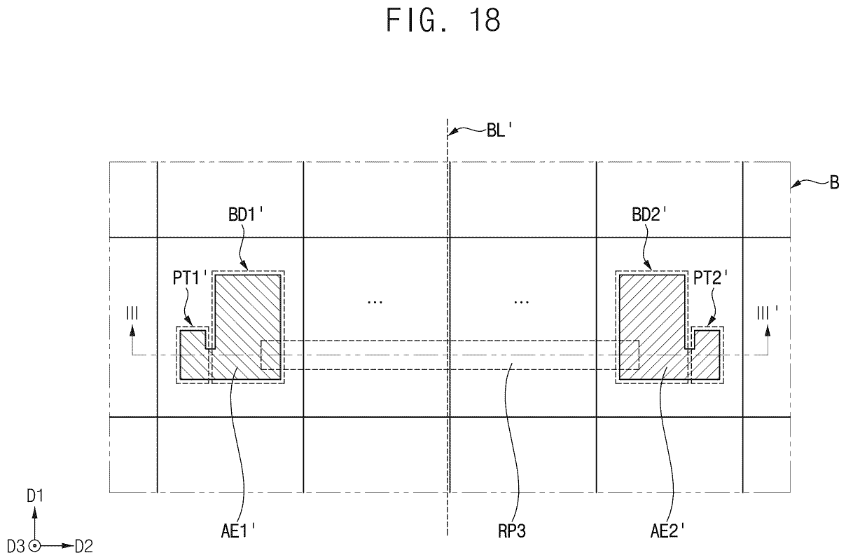

Thereafter, referring to FIG. 16, the first welding part WD1 and the second welding part WD2 may be formed through a welding process. For example, the first welding part WD1 may be formed through the welding process in an area where the repair pattern RP2 and the first pixel electrode AE1 overlap, and the second welding part WD2 may be formed through the welding process in an area where the repair pattern RP2 and the second pixel electrode AE2 overlap. Accordingly, the first welding part WD1 may be formed contacting the first pixel electrode AE1 and the repair pattern RP2, and the second welding part WD2 may be formed contacting the second pixel electrode AE2 and the repair pattern RP2.

Accordingly, the first pixel electrode AE1 and the second pixel electrode AE2 may be electrically connected through the first welding part WD1 and the second welding part WD2 with the repair pattern RP2 interposed

The first welding part WD1 may electrically connect the first pixel electrode AE1 and the repair pattern RP2. The second welding part WD2 may electrically connect the second pixel electrode AE2 and the repair pattern RP2. For example, the first welding part WD1 and the second welding part WD2 may allow substantially the same current to flow through the first pixel electrode AE1 and the second pixel electrode AE2 through the repair pattern RP2.

According to some embodiments, the first welding part WD1 and the second welding part WD2 may be formed using a laser. That is, the welding process may be performed using a laser. For example, the laser used in the welding process may be an ultra-fast laser. For example, the ultra-fast laser may be a picosecond laser, a femtosecond laser, or an attosecond laser. However, embodiments according to the present invention are not necessarily limited thereto.

FIG. 17 is a plan view showing a display device according to some embodiments of the present invention.

A display device 2000 described with reference to FIG. 17 may be substantially the same as those described with reference to FIG. 1 except for including a first pixel area PA1′, a second pixel area PA2′, a third pixel area PA3, a fourth pixel area PA4, a first pixel PX1′, a second pixel PX2′, a third pixel PX3, and a fourth pixel PX4. Therefore, overlapping explanations may be omitted or simplified.

That is, the configuration shown in FIG. 17 may be substantially the same as those shown in FIG. 1 except for including the first pixel area PA1′, the second pixel area PA2′, the third pixel area PA3, the fourth pixel area PA4, the first pixel PX1′, and the second pixel PX2′ the third pixel PX3 and the fourth pixel PX4 instead of the first pixel area PA1, the second pixel area PA2, the first pixel PX1, and the second pixel PX2.

According to some embodiments, the pixel areas may include the first pixel area PA1′, the second pixel area PA2′, the third pixel area PA3, and the fourth pixel area PA4. The first pixel area PA1′, the second pixel area PA2′, the third pixel area PA3, and the fourth pixel area PA4 may be arranged along the second direction D2.

For example, the third pixel area PA3 may be adjacent to the first pixel area PA1′ in the second direction D2, the fourth pixel area PA4 may be adjacent to the third pixel area PA3 in the second direction D2, and the second pixel area PA2′ may be adjacent to the fourth pixel area PA4 in the second direction D2. That is, the second pixel area PA2′ is separated with the first pixel area PA1′ in the second direction D2 with the third pixel area PA3 and the fourth pixel area PA4 interposed therebetween.

The first pixel PX1′ may be located in the first pixel area PA1′, the second pixel PX2′ may be located in the second pixel area PA2′, the third pixel PX3 may be located in the area PA3, and the fourth pixel PX4 may be located in the fourth pixel area PA4.

Accordingly, the third pixel PX3 may be adjacent to the first pixel PX1′ in the second direction D2, the fourth pixel PX4 may be adjacent to the third pixel PX3 in the second direction D2, and the second pixel PX2′ may be adjacent to the fourth pixel PX4 in the second direction D2. That is, the second pixel PX2′ may be spaced apart from the first pixel PX1′ in the second direction D2 with the third pixel PX3 and the fourth pixel PX4 interposed therebetween.

According to some embodiments, a color of light emitted by the first pixel PX1′ and a color of light emitted by the second pixel PX2′ may be the same. In other words, a color of light emitted from the first pixel area PA1′ and a color of light emitted from the second pixel area PA2′ may be the same.

For example, a color of light emitted from the first pixel PX1′ and a color of light emitted from the second pixel PX2′ may be red. For another example, a color of light emitted from the first pixel PX1′ and a color of light emitted from the second pixel PX2′ may be green. For still another example, a color of light emitted from the first pixel PX1′ and a color of light emitted from the second pixel PX2′ may be blue. However, the present invention may not be necessarily limited to this, and a color of light emitted from the first pixel PX1′ and the second pixel PX2′ may vary in various embodiments.

Additionally, a color of light emitted from the third pixel PX3 may be different from a color of light emitted from the first pixel PX1′ and the second pixel PX2′, and a color of light emitted from the fourth pixel PX4 may be different from a color of light emitted from the first pixel PX1′ and the second pixel PX2′. In other words, a color of the light emitted from the third pixel area PA3 may be different from a color of the light emitted from the first pixel area PA1′ and the second pixel area PA2′, and a color of light emitted from the pixel area PA4 may be different from a color of light emitted from the first pixel area PA1′ and the second pixel area PA2′.

Additionally, a color of light emitted by the third pixel PX3 may be different from a color of light emitted by the fourth pixel PX4. In other words, a color of light emitted from the third pixel area PA3 may be different from a color of light emitted from the fourth pixel area PA4.

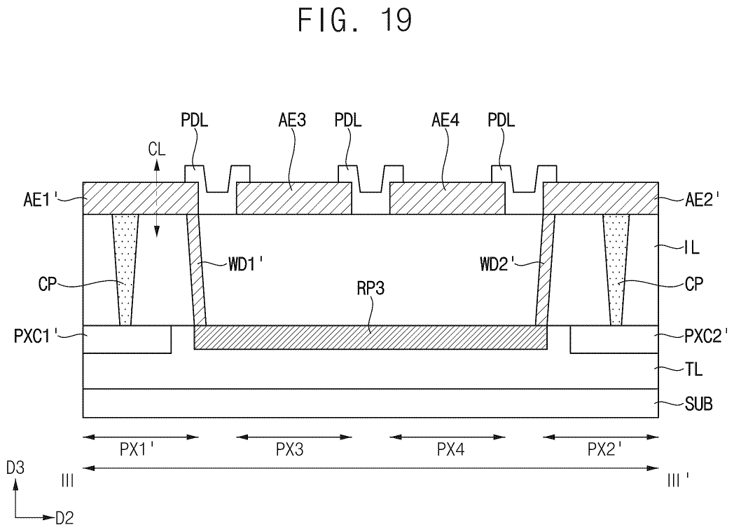

FIG. 18 is an enlarged view showing an example of part B of FIG. 17. For example, FIG. 18 is an enlarged view schematically showing an example of the arrangement of the first and the second pixel electrodes AE1′ and AE2′ and the repair pattern RP3 in area B of FIG. 17.

Referring to FIGS. 17 and 18, the first pixel electrode AE1′ of the first pixel PX1′ may be located in the first pixel area PA1′, and the second pixel electrode AE2′ of the second pixel PX2′ may be located in the second pixel area PA2′.

Accordingly, the first pixel electrode AE1′ and the second pixel electrode AE2′ may be spaced apart from each other along the second direction D2. For example, the first pixel electrode AE1′ and the second pixel electrode AE2′ may be spaced apart in the second direction D2 with the electrode located in the third pixel area PA3 and the fourth pixel area PA4 interposed therebetween.

According to some embodiments, as shown in FIG. 18, the first pixel electrode AE1′ and the second pixel electrode AE2′ may be line symmetrical with respect to the reference line BL′ on a plane. However, embodiments according to the present invention are not necessarily limited thereto.

For example, the first pixel electrode AE1′ may include first body BD1′ and a first protrusion PT1′ protruding from one side of the first body BD1′ in a direction opposite to the second direction D2. The second pixel electrode AE2′ may include a second body BD2′ and a second protrusion PT2′ protruding from one side of the second body BD2′ in the second direction D2. However, embodiments according to the present invention are not necessarily limited thereto.

The first pixel electrode AE1′ and the second pixel electrode AE2′ may include metal, alloy, metal nitride, conductive metal oxide, transparent conductive material, and the like. These may be used alone or in combination with each other. For example, the first pixel electrode AE1′ and the second pixel electrode AE2′ may be an anode electrode.

The repair pattern RP3 may be located below the first pixel electrode AE1′ and the second pixel electrode AE2′. According to some embodiments, the repair pattern RP3 may be arranged to overlap the first pixel electrode AE1′ and the second pixel electrode AE2′.

According to some embodiments, the repair pattern RP3 may be in contact with the first pixel electrode AE1′ and the second pixel electrode AE2′, and may electrically connect the first pixel PX1′ and the second pixel PX2′. For example, the repair pattern RP3 may include metal, alloy, metal nitride, conductive metal oxide, transparent conductive material, and the like. These may be used alone or in combination with each other.

FIG. 19 is a cross-sectional view taken along the line III-III′ of FIG. 18.

The configurations described with reference to FIG. 19 may be substantially the same as those described with reference to FIG. 13 except for the first pixel electrode AE1′, the second pixel electrode AE2′, the third pixel electrode AE3, the fourth pixel electrode AE4, the first welding part WD1′, the second welding part WD2′, and the repair pattern RP3. Therefore, overlapping explanations may be omitted or simplified.

That is, the configuration shown in FIG. 19 may be substantially the same as that shown in FIG. 13 except for including the first pixel electrode AE1′, the second pixel electrode AE2′, the third pixel electrode AE3, the fourth pixel electrode AE4, the first welding part WD1′, the second welding part WD2′, and the repair pattern RP3 instead of the first pixel electrode AE1, the second pixel electrode AE2, the first welding part WD1, the second welding part WD2, and the pattern RP2.

Referring to FIGS. 17 and 19, the display device 2000 may include the substrate SUB, the transistor layer TL, the insulating layer IL, the connection pattern CP, and the first welding part WD1′, the second welding part WD2′, the first pixel electrode AE1′, the second pixel electrode AE2′, the third pixel electrode AE3, and the fourth pixel electrode AE4 and the pixel defining layers PDL.

The transistor layer TL may be located on the substrate SUB. The transistor layer TL may include a first pixel circuit unit PXC1′ and a second pixel circuit unit PXC2′. The first pixel circuit unit PXC1′ and the second pixel circuit unit PXC2′ may include various driving elements, wiring, and the like for driving the light-emitting element of the first pixel PX1′ and the light-emitting element of the second pixel PX2′.

According to some embodiments, the transistor layer TL may include the repair pattern RP3. The repair pattern RP3 may be located on the same layer as one of several metal patterns located on the transistor layer TL. In other words, the repair pattern RP3 may be formed in the same process as any one of several metal patterns located on the transistor layer TL.

Specifically, the repair pattern RP3 may be located on the same layer as one of several metal patterns forming the first pixel circuit unit PXC1′ and/or the second pixel circuit unit PXC2′. In other words, the repair pattern RP3 may be formed in the same process as one of several metal patterns forming the first pixel circuit unit PXC1′ and/or the second pixel circuit unit PXC2′.

The repair pattern RP3 may be in contact with the first pixel electrode AE1′ and the second pixel electrode AE2′, and may electrically connect the first pixel PX1′ and the second pixel PX2′. For example, the repair pattern RP3 may cause the same current to flow through the first pixel electrode AE1′ and the second pixel electrode AE2′. The repair pattern RP3 may include metal, alloy, metal nitride, conductive metal oxide, transparent conductive material, and the like. These may be used alone or in combination with each other.

For example, the repair pattern RP3 may electrically connect the first pixel PX1′ and the second pixel PX2′ through a welding process. That is, the first welding part WD1′ may be formed through the welding process in an area where the repair pattern RP3 and the first pixel electrode AE1′ overlap, and the second welding part WD2′ may be located through the welding process in an area where the repair pattern RP3 and the second pixel electrode AE2′ overlap. Accordingly, the first welding part WD1′ may be in contact with the first pixel electrode AE1′ and the repair pattern RP3, and the second welding part WD2′ may be in contact with the second pixel electrode AE2′ and the repair pattern RP3.

Accordingly, the repair pattern RP3 may be electrically connected to the first pixel electrode AE1′ through the first welding part WD1′ and may be electrically connected to the pixel electrode AE2′ through the second welding part WD2′. In other words, the first pixel electrode AE1′ and the second pixel electrode AE2′ may be electrically connected through the first welding part WD1′ and the second welding part WD2′ with the repair pattern RP3 interposed.

According to some embodiments, the repair pattern RP3 may be formed to overlap the first pixel electrode AE1′ and the second pixel electrode AE2′ on a plane.

The insulating layer IL may be located on the transistor layer TL. The insulating layer IL may be located in pixel areas. The insulating layer IL may prevent contact between the pixel electrodes AE1′, AE2′, AE3, and AE4 and the pixel circuit units PXC1′ and PXC2′.

Contact holes penetrating the insulating layer IL may be defined in the insulating layer IL. The contact holes may expose the first pixel circuit unit PXC1′ and the second pixel circuit unit PXC2′, respectively. Each of the contact holes may be filled with the connection pattern CP. The connection pattern CP may be electrically connected to the first pixel circuit unit PXC1′ and the second pixel circuit unit PXC2′. For example, the connection pattern CP located in the first pixel area PA1′ may be electrically connected to the first pixel circuit unit PXC1′ and the connection pattern CP located in the second pixel area PA2′ may be electrically connected to the second pixel circuit unit PXC2′.

The first welding part WD1′ and the second welding part WD2′ may be formed on the insulating layer through a welding process. For example, the repair pattern RP3 may electrically connect the first pixel PX1′ and the second pixel PX2′ through the welding process. That is, the first welding part WD1′ may be formed through the welding process in an area where the repair pattern RP3 and the first pixel electrode AE1′ overlap, and the second welding part WD2′ may be formed through the welding process in an area where the repair pattern RP3 and the second pixel electrode AE2′ overlap. Accordingly, the first welding part WD1′ may be in contact with the first pixel electrode AE1′ and the repair pattern RP3, and the second welding part WD2′ may be in contact with the second pixel electrode AE2′ and repair pattern RP3.

Accordingly, the repair pattern RP3 may be electrically connected to the first pixel electrode AE1′ through the first welding part WD1′ and may be electrically connected to the pixel electrode AE2′ through the second welding part WD2′. In other words, the first pixel electrode AE1′ and the second pixel electrode AE2′ may be electrically connected through the first welding part WD1′ and the second welding part WD2′ with the repair pattern RP3 interposed therebetween.

The first pixel electrode AE1′, the second pixel electrode AE2′, the third pixel electrode AE3, and the fourth pixel electrode AE4 may be located on the insulating layer IL. For example, the first pixel electrode AE1′ may be located on the insulating layer IL corresponding to the first pixel area PA1′, the second pixel electrode AE2′ may be located on the insulating layer IL corresponding to the second pixel area PA2′, the third pixel electrode AE3 may be located on the insulating layer IL corresponding to the third pixel area PA3′, and the fourth pixel electrode AE4 may be located on the insulating layer IL corresponding to the fourth pixel area PA4. The first pixel electrode AE1′ may be electrically connected to the first pixel circuit unit PXC1′ through the connection pattern CP, and the second pixel electrode AE2′ may be electrically connected to the second circuit unit PXC2′ through the connection pattern CP.

The pixel defining layer PDL may be located on the insulating layer IL, the first pixel electrode AE1′, the second pixel electrode AE2′, the third pixel electrode AE3, and the fourth pixel electrode AE4. The pixel defining layer PDL may cover a portion of each of the first pixel electrode AE1′, the second pixel electrode AE2′, the third pixel electrode AE3, and the fourth pixel electrode AE4. That is, the pixel defining layer PDL may expose a portion of each of the first pixel electrode AE1′, the second pixel electrode AE2′, the third pixel electrode AE3, and the fourth pixel electrode AE4. For example, the pixel defining layer PDL may cover side portions of each of the first pixel electrode AE1′ and the second pixel electrode AE2′, and may expose a central portion of each of the first pixel electrode AE1′ and the second pixel electrode AE2′.

According to some embodiments, when a defect occurs in any one of pixels arranged to be spaced apart from each other, the defective pixel may be repaired. For example, when a defect occurs in one of the first pixel PX1′ and the second pixel PX2′, the defective pixel may be repaired through the repair pattern RP3.

A display device according to various embodiments of the present invention may include the substrate SUB including a first pixel area and a second pixel area, the first pixel located in the first pixel area on the substrate SUB and including the first pixel electrode, the second pixel area located in the second pixel area on the substrate SUB and including the second pixel electrode, and a repair pattern located on and/or below the first pixel electrode and the second pixel electrode and electrically connecting the first pixel PX1 and the second pixel PX2.

Therefore, before the light emitting layer EL is formed on the first pixel electrode and the second pixel electrode, a repair may be performed to prevent the occurrence of bright spots and dark spots due to defective pixels. Accordingly, productivity and yield of the display device may be relatively improved. In addition, even when the design constraints of the display device for repair are minimized and the degree of integration of the display device is high, the above repair pattern may be relatively easily formed.

Also, according to the repair method according to embodiments of the present invention, after forming the repair pattern, an additional data voltage may be applied to the first pixel and the second pixel to prevent current reduction due to repair. Accordingly, the phenomenon of luminance being lowered due to repair may be prevented or reduced.

Although certain embodiments and implementations have been described herein, other embodiments and modifications will be apparent from this description. Accordingly, the inventive concepts are not limited to such embodiments, but rather embodiments according to the present disclosure are defined by the appended claims, and their equivalents.

What is claimed is:

1. A display device comprising:
a substrate including a first pixel area and a second pixel area adjacent to each other along a first direction;
a first pixel in the first pixel area on the substrate and including a first pixel electrode;
a second pixel in the second pixel area on the substrate and including a second pixel electrode; and
a repair pattern on the first pixel electrode and the second pixel electrode, contacting with the first pixel electrode and the second pixel electrode, and electrically connecting the first pixel and the second pixel.

2. The display device of claim 1, further comprising:
a pixel defining layer covering a portion of the first pixel electrode and a portion of the second pixel electrode, and
wherein the repair pattern is on the pixel defining layer.

3. The display device of claim 1, wherein the repair pattern includes a metal material.

4. The display device of claim 1, wherein each of the first pixel electrode and the second pixel electrode includes a body portion and a protrusion protruding from one side of the body portion.

5. The display device of claim 4, in a plan view, wherein the first pixel electrode and the second pixel electrode are line symmetrical with respect to a reference line extending between the first pixel electrode and the second pixel electrode in a second direction intersecting the first direction,
the protrusion of the first pixel electrode protrudes from the body portion of the first pixel electrode in the first direction, and
the protrusion of the second pixel electrode protrudes from the body portion of the second pixel electrode in a direction opposite to the first direction.

6. The display device of claim 4, in a plan view, wherein the first pixel electrode and the second pixel electrode are repeatedly arranged in a same shape along the first direction,
the protrusion of the first pixel electrode protrudes from the body portion of the first pixel electrode in the first direction, and
the protrusion of the second pixel electrode protrudes from the body portion of the second pixel electrode in the first direction.

7. The display device of claim 1, wherein a color of light emitted by the first pixel and a color of light emitted by the second pixel are the same.

8. A display device comprising:
a substrate including a first pixel area and a second pixel area;
a first pixel in the first pixel area on the substrate and including a first pixel electrode;
a second pixel in the second pixel area on the substrate and including a second pixel electrode;
a repair pattern below the first pixel electrode and the second pixel electrode, contacting with the first pixel electrode and the second pixel electrode, and electrically connecting the first pixel and the second pixel.

9. The display device of claim 1, wherein the repair pattern overlaps the first pixel electrode and the second pixel electrode in a plan view.

10. The display device of claim 8, wherein a color of light emitted by the first pixel and a color of light emitted by the second pixel are the same.

11. The display device of claim 8, further comprising:
a first welding part contacting with the first pixel electrode; and
a second welding part contacting with the second pixel electrode, and
wherein the first welding part and the second welding part are in contact with the repair pattern.

12. A method of repairing a display device including a substrate including a first pixel area and a second pixel area, a first pixel in the first pixel area and including a first pixel electrode, and a second pixel in the second pixel area and including a second pixel electrode, the method comprising:
cutting a portion of the first pixel electrode;
electrically connecting the first pixel electrode and the second pixel electrode through a repair pattern contacting with the first pixel electrode and the second pixel electrode; and
applying an additional data voltage to the first pixel and the second pixel.

13. The method of claim 12, wherein in the cutting the portion of the first pixel electrode, the first pixel electrode is cut using a laser.

14. The method of claim 12, wherein the first pixel electrode includes a body portion and a protrusion protruding from one side of the body portion, and
in the cutting the portion of the first pixel electrode, the protrusion is cut from the body portion.

15. The method of claim 12, further comprising:
forming a light emitting layer on the first pixel electrode and the second pixel electrode; and
forming a common electrode on the light emitting layer, and
wherein the forming the light emitting layer and the forming the common electrode are performed after the electrically connecting the first pixel electrode and the second pixel electrode.

16. The method of claim 12, further comprising:
forming a pixel defining layer covering a portion of the first pixel electrode and a portion of the second pixel electrode, and
wherein the electrically connecting the first pixel electrode and the second pixel electrode includes forming the repair pattern on the pixel defining layer.

17. The method of claim 16, wherein the repair pattern is formed using a laser chemical vapor deposition (CVD) method.

18. The method of claim 12, wherein the repair pattern is below the first pixel electrode and the second pixel electrode and overlaps the first pixel electrode and the second pixel electrode in a plan view, and
the electrically connecting the first pixel electrode and the second pixel electrode includes:
forming a first welding part contacting with the repair pattern and the first pixel electrode; and
forming a second welding part contacting with the repair pattern and the second pixel electrode.

19. The method of claim 12, wherein in the applying the additional data voltage,
a basic current based on a basic data voltage and an additional current based on the additional data voltage are applied to each of the first pixel electrode and the second pixel electrode.

20. The method of claim 19, wherein a magnitude of the basic current applied to each of the first pixel and the second pixel and a magnitude of the additional current applied to each of the first pixel and the second pixel are equal.
